(19) United States
(12) Patent Application Publication
(10) Pub. No.: US 2026/0002258 A1
(43) Pub. Date: Jan. 1, 2026

(54) METHODS AND APPARATUS FOR EXHAUST BIAS

(71) Applicant: ASM IP Holding B.V., Almere (NL)

(72) Inventors: Rajmohan Muthaiah, Phoenix, AZ (US); Ruchik Jayeskumar Bhatt, Chandler, AZ (US); Kalayarasan Seranthian, Tempe, AZ (US); Shashank Terala, Phoenix, AZ (US); Kranthi Kumar Vaidyula, Chandler, AZ (US); Sukanya Datta, Phoenix, AZ (US); YoungChol Byun, Tempe, AZ (US)

(21) Appl. No.: 19/248,796

(22) Filed: Jun. 25, 2025

Related U.S. Application Data
(60) Provisional application No. 63/665,446, filed on Jun. 28, 2024.

(51) Int. Cl. C23C 16/455; C23C 16/44; C23C 16/52

(52) U.S. Cl. CPC C23C 16/45544; C23C 16/4412; C23C 16/45508; C23C 16/52

(57) ABSTRACT

Various embodiments of the present technology may provide a flow control ring disposed between an exhaust plate and a reaction chamber, the flow control ring including a plurality of sections, wherein the plurality of sections consists of a first quarter section, a second quarter section, a third quarter section, and a fourth quarter section, and wherein the second, third, and fourth sections have a first height and the first section has a second height that is greater than the first height.

### CROSS-REFERENCE TO RELATED APPLICATIONS

This application is a nonprovisional of, and claims priority to and the benefit of, U.S. Provisional Patent Application No. 63/665,446, filed Jun. 28, 2024 and entitled “METHODS AND APPARATUS FOR EXHAUST BIAS,” which is hereby incorporated by reference herein.

### FIELD OF INVENTION

The present disclosure generally relates to a method and apparatus for exhaust bias. More particularly, the present disclosure relates to a flow control ring having variable heights to bias the exhaust gas flow.

### BACKGROUND OF THE TECHNOLOGY

Reaction chambers used in semiconductor manufacturing may utilize a flow control ring in conjunction with an exhaust system to remove gas from the reaction space. When the flow of exhaust gas is not uniform, thickness uniformity of a film on the wafer may be negatively impacted.

### SUMMARY OF THE INVENTION

Various embodiments of the present technology may provide a flow control ring disposed between an exhaust plate and a reaction chamber, the flow control ring including a plurality of sections, wherein the plurality of sections consists of a first quarter section, a second quarter section, a third quarter section, and a fourth quarter section, and wherein the second, third, and fourth sections have a first height and the first section has a second height that is greater than the first height.

According to one aspect, an apparatus, comprises: a reaction chamber comprising a sidewall; a gas distribution system arranged above the reaction chamber and comprising: a showerhead plate comprising an inlet plenum fluidly coupled to a plurality of inlet through-holes; and an exhaust plate comprising an exhaust plenum; a gate valve disposed within the sidewall of the reaction chamber; an exhaust port disposed within the sidewall of the reaction chamber; and a flow control ring disposed between the exhaust plate and the reaction chamber, and comprising a plurality of sections, wherein at least one section has a height that is greater than a height of a different section.

In one embodiment, the plurality of sections consists of a first quarter section, a second quarter section, a third quarter section, and a fourth quarter section.

In one embodiment, the second, third, and fourth sections have a first height and the first section has a second height that is greater than the first height.

In one embodiment, the first section is radially aligned with the gate valve.

In one embodiment, the first section is radially aligned with the gate valve and the exhaust port.

In one embodiment, the first height has a range from 8 mm to 13 mm and the second height has range from 8 mm to 13 mm.

In one embodiment, the flow control ring comprises a top surface comprising a first region having an upward tapered profile in a first direction and a second region having a downward tapered profile in an opposite, second direction.

In one embodiment, the top surface further comprises a third region having a horizontal profile disposed between the first and second regions, the horizontal profile having a width of 10 mm to 20 mm.

In one embodiment, the flow control ring and exhaust plate are separated by a gap in the range of 0.1 mm to 2 mm.

In one embodiment, the flow control ring comprises a top surface having a tapered profile.

In another aspect, an apparatus comprises: a reaction chamber; a gas distribution system arranged above the reaction chamber and comprising: a showerhead plate comprising an inlet plenum fluidly coupled to a plurality of inlet through-holes; and an exhaust plate comprising an exhaust plenum; and a flow control ring disposed between the exhaust plate and the reaction chamber, and comprising a plurality of sections, wherein the plurality of sections consists of a first quarter section, a second quarter section, a third quarter section, and a fourth quarter section, and wherein the second, third, and fourth sections have a first height and the first section has a second height that is greater than the first height.

In one embodiment, the flow control ring and exhaust plate are separated by a gap in the range of 0.1 mm to 2 mm.

In one embodiment, the flow control ring comprises a top surface having a tapered profile.

In one embodiment, the flow control ring comprises a top surface comprising a first region having a tapered profile in a first direction and a second region having a tapered profile in an opposite, second direction.

In one embodiment, the top surface further comprises a third region having a horizontal profile disposed between the first and second regions, the horizontal profile having a width of 10 mm to 20 mm.

In one embodiment, the tapered profiles are linear.

In one embodiment, the first height has a range from 8 mm to 13 mm and the second height has range from 8 mm to 13 mm.

In yet another aspect, an apparatus comprises: a reaction chamber comprising a sidewall; an exhaust plate disposed above the reaction chamber and comprising an exhaust plenum; a gate valve disposed within the sidewall of the reaction chamber; an exhaust port disposed within the sidewall of the reaction chamber; and a flow control ring disposed between the exhaust plate and the reaction chamber, and comprising a plurality of sections, wherein at least one section comprises a top surface having a linearly-tapered profile and a height that is greater than a height of a different section.

In one embodiment, the top surface further comprises a region having a horizontal profile disposed between the first and second regions, the horizontal profile having a width of 10 mm to 20 mm.

In one embodiment, the at least one section is radially aligned with at least one of the gate valve and the exhaust port.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIGS. 2A-2B are cross-sectional views of a reactor in accordance with embodiments of the present technology;

FIGS. 3A-3B are top views of a flow control ring in accordance with embodiments of the present technology;

FIG. 4 is side view of the flow control ring in accordance with embodiments of the present technology;

FIG. 5 is a side view of the flow control ring in accordance with embodiments of the present technology; and

FIG. 6 is a top view of an exhaust disk in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, reaction chambers, vessels, and susceptors.

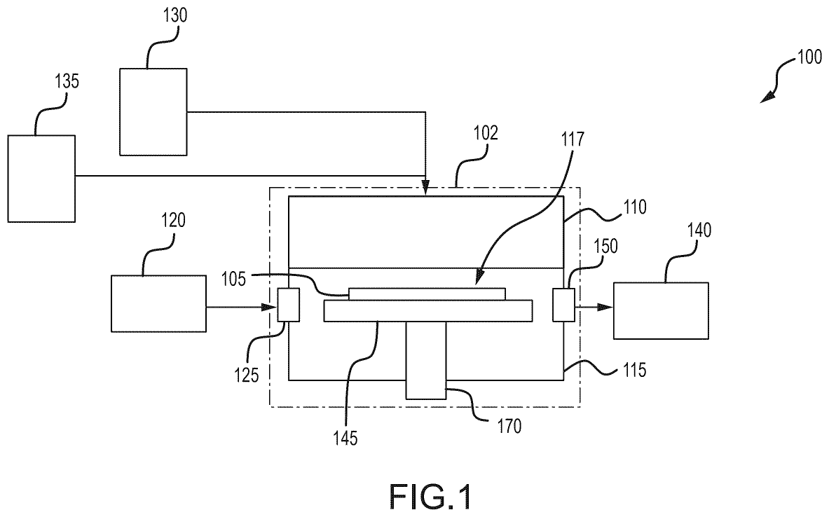

Referring to FIG. 1, an exemplary system 100 may comprise a reactor 102 configured to perform processing on an object to be processed, such as a substrate 105 (e.g., a wafer). For example, the reactor 102 may be configured to perform heating, deposition, etching, polishing, ion implantation, and/or other processing on the object to be processed. In some embodiments, the reactor 102 may be configured to perform a movement function, a vacuum sealing function, and an exhaust function. In some embodiments, the reactor 102 may perform an atomic layer deposition (ALD) process or a chemical vapor deposition (CVD) process.

In various embodiments, the system 100 may comprise an exhaust system 140 to facilitate evacuation of gas from the reactor 102. For example, the exhaust system 140 may comprise a foreline (not shown) and a pump (e.g., a vacuum pump) (not shown) to facilitate evacuation of gas from the reactor 102.

In an exemplary embodiment, the reactor 102 may comprise a reaction chamber 115 comprising a reaction space 117 above and/or around the substrate 105. For example, the reaction chamber 115 may comprise sidewalls and a bottom coupled to the sidewalls.

In an exemplary embodiment, the reaction chamber 115 may comprise a gate valve 125 disposed within a vertical sidewall of the reaction chamber 115. The gate valve 125 may be used to allow transfer of the substrate 105 from a wafer holding space 120 to the reaction chamber 115. For example, a robot (not shown) may be utilized to physically move the substrate from the wafer holding space 120, through the gate valve 125, and into the reaction chamber 115. The gate valve 125 may be controlled by a controller (not shown). For example, the controller may signal the gate valve 125 to open during substrate transfer and close after the substrate has been placed on the susceptor 145.

In an exemplary embodiment, the reaction chamber 115 may further comprise an exhaust port 150. The exhaust port 150 may be disposed within a sidewall of the reaction chamber or a top surface of the reactor 102. The exhaust port 150 may be configured to couple the reactor 102 to the exhaust system 140.

In various embodiments, the system 100 may further comprise a substrate mounting unit disposed within the reaction chamber 115 of the reactor 102. The substrate mounting unit may comprise a susceptor 145 for supporting the substrate 105 and a heater (not shown) for heating the substrate 105 supported by the susceptor 145. The heater may be embedded within the susceptor 145. The substrate mounting unit may further comprise a pedestal 170 to support the susceptor 145. For loading/unloading of the substrate 105, the substrate mounting unit may be configured to be vertically movable (up and down) by being connected to a driving unit (not shown). The susceptor 145 may be disposed in or adjacent the reaction space 117. For example, the susceptor 145 may be arranged to position the substrate 105 in the reaction space 117.

In various embodiments, the reactor 102 may further comprise a gas distribution system 110 for delivering a vapor into the reaction chamber 115. In an exemplary embodiment, the gas distribution system 110 is arranged above the susceptor 145.

In various embodiments, the gas distribution system 110 may be arranged adjacent to the reaction chamber 115. For example, the gas distribution system 110 may be disposed on the sidewalls of the reaction chamber 115, opposite from the bottom of the reaction chamber 115. In some embodiments, the gas distribution system 110 may be fastened to the sidewalls, however, in other cases, the gas distribution system 110 may merely rest on the sidewalls of the reaction chamber 115. In various embodiments, the gas distribution system 110 together with the reaction chamber 115 sidewalls form an enclosed space, including the reaction space 117.

In various embodiments, the system 100 may further comprise a vessel 135 configured to contain a chemical (i.e., a precursor). The vessel 135 may be configured to hold a solid or a liquid chemical, and may further be configured to transform the solid or liquid into a vapor. The vessel 135 may be coupled to the gas distribution system 110. For example, the system 100 may further comprise various gas conduits (not shown) and/or valves (not shown) to flow the vapor from the vessel 135 into the gas distribution system 110.

In various embodiments, the system 100 may further comprise an inert gas source 130 configured to contain an inert gas, such as an argon or the like. The inert gas source 130 may be fluidly coupled to the gas distribution system 110 via any number of gas lines/conduits and/or valves.

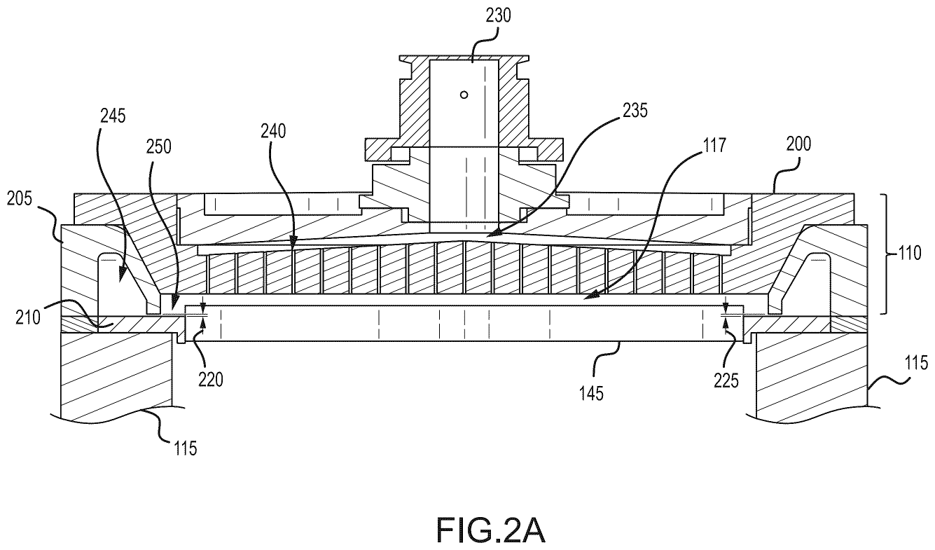

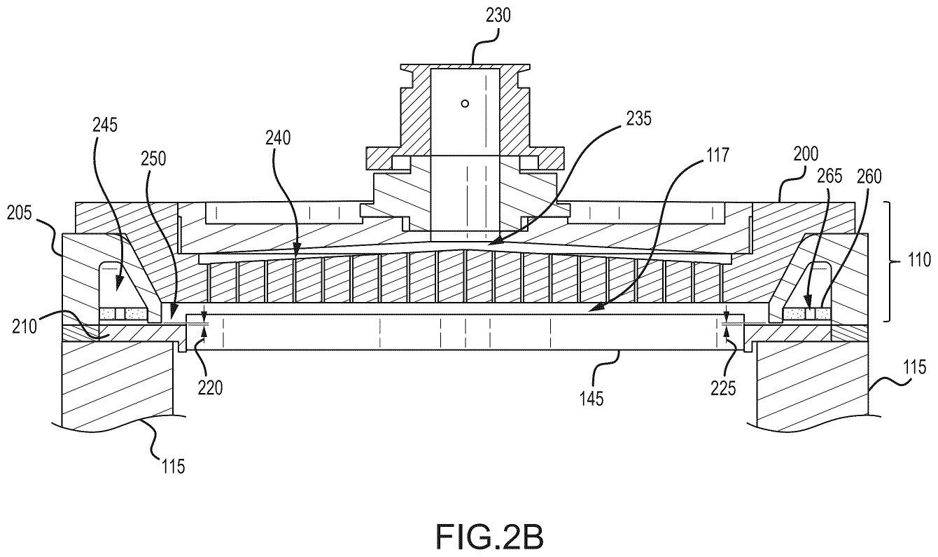

In an exemplary embodiment, and referring to FIGS. 1-2, the gas distribution system 110 may comprise a showerhead plate 200 to deliver vapor to the reaction space 117. In an exemplary embodiment, the showerhead plate 200 may comprise an inlet plenum 235 configured to receive vapor from the vessel 135. For example, the inlet plenum 235 may be coupled to the vessel 135 with an inlet 230.

In an exemplary embodiment, the showerhead plate 200 may further comprise a plurality of inlet through-holes 240 that extend through a portion of the showerhead plate 200. For example, the plurality of through-holes 240 may fluidly couple the inlet plenum 235 and the reaction space 117. For example, the vapor that flows into the inlet plenum 235 from the vessel 135 may continue to flow through the plurality of through-holes 240 The plurality of inlet through-holes 300 may also be in fluid communication with the reaction space 117. For example, the vapor may flow through the plurality of inlet through-holes 240 and into the reaction space 117. The plurality of inlet through-holes 240 may contain approximately 1000-1200 through-holes. The plurality of inlet through-holes 240 may be arranged within a central region (also referred to as a showerhead region) of the showerhead plate 200.

In some embodiments, the inlet plenum 235 and the plurality of through-holes 240 may be formed within a single structure. In other embodiments, the inlet plenum 235 and the plurality of through-holes 240 may be formed within two distinct structures that are arranged directly adjacent to each other.

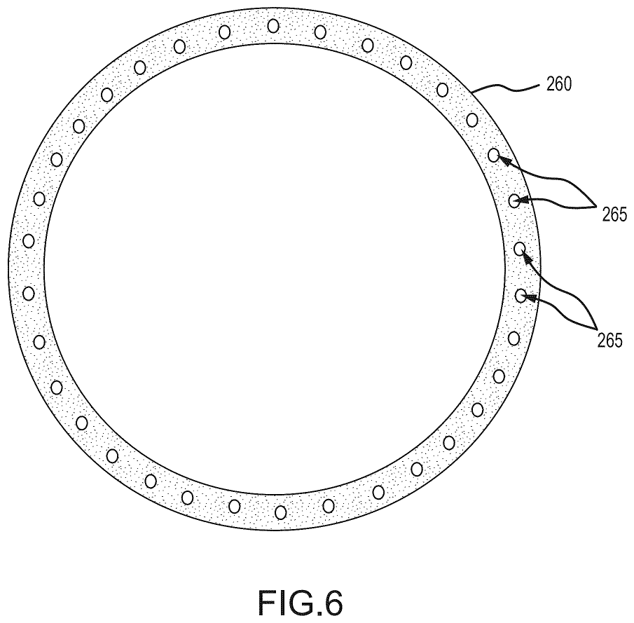

In various embodiments, and referring to FIGS. 2A-2B and 6, the gas distribution system 110 may further comprise an exhaust plate 205 comprising an exhaust plenum 245. The exhaust plenum 245 may be fluidly coupled to the exhaust port 150. For example, gas may flow from the exhaust plenum 245 and into the exhaust system 140 via the gas port 150. In various embodiments, the exhaust plenum 245 may be arranged concentric with the inlet plenum 235. For example, the exhaust plenum 245 may have a ring shape that surrounds and is larger than the inlet plenum 235. The exhaust plate 205 may be in direct contact with the sidewalls of the reaction chamber 115. For example, the exhaust plate 205 may rest on the sidewalls or may be fastened to them.

In various embodiments, the exhaust plate 205 may further comprise an exhaust disk 260 disposed within the exhaust plenum 245 and configured to restrict gas flow into the exhaust plenum 245. The exhaust disk 260 may comprise a plurality of through-holes 265 extending horizontally through a top and a bottom of the exhaust disk 260. The plurality of through-holes 265 may be in fluid communication with the exhaust plenum 245. In various embodiments, the exhaust plate 205 and the exhaust disk 260 may be formed from a ceramic material, such as aluminum oxide or the like. The exhaust disk 260 may be affixed to the inner sidewalls of the exhaust plenum 245 such that gas flows only through the through-holes 265. The plurality of through-holes 265 may comprise any suitable number of through-holes and each through-hole diameter may be in the range of 0.2 mm to 5 mm. The plurality of through-holes 265 may be spaced equidistant from each other. Alternatively, there may be one or more groups of through-holes that have a more narrow spacing than one or more other groups.

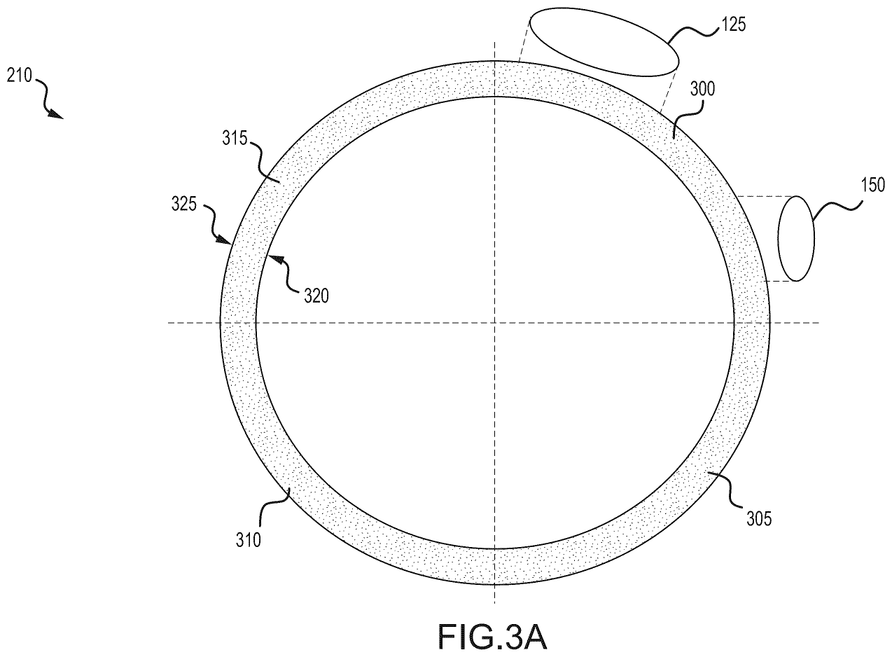

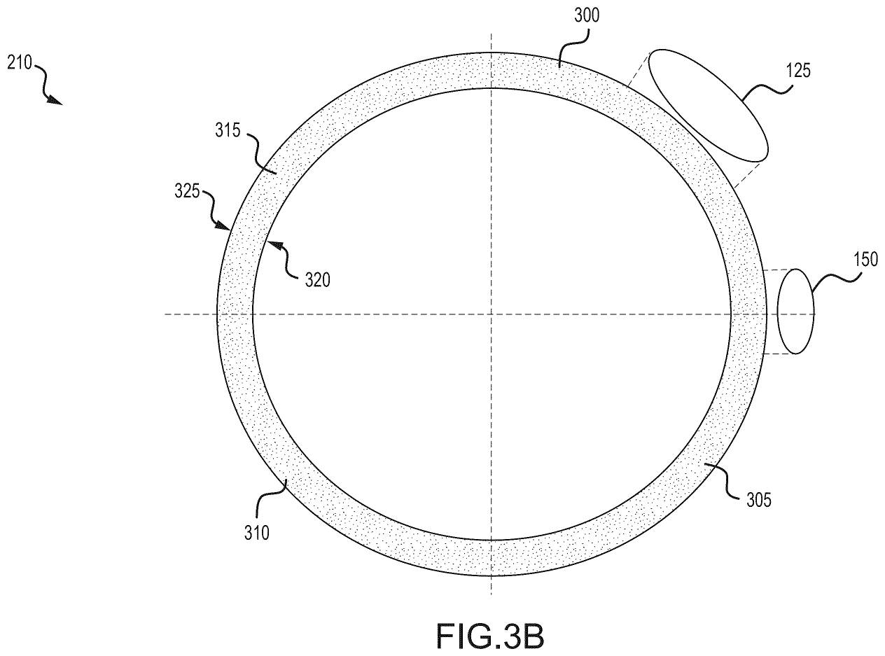

Referring to FIGS. 2-5, the system 100 may further comprise a flow control ring 210 configured to direct gas flow from the reaction space 117 to the exhaust plenum 245. The flow control ring 210 may be disposed between the reaction chamber 115 and the exhaust plate 205. In an exemplary embodiment, a top surface 250 of the flow control ring 210 and the exhaust plate 205 (and/or the exhaust disk 260) may be separated by a gap, such as a first gap 220 and a second gap 225. In various embodiments, the second gap 225 may be smaller than the first gap 220, and the first and second gaps 220, 225 may range from 0.1 mm to 2 mm. For example, the first gap 220 may be 1.5 mm and the second gap 225 may be 1 mm. In various embodiments, the flow control ring 210 may be circular in shape and having an inner wall 320 having an inner diameter in the range of 300-400 mm and an outer edge 325 having an outer diameter in the range of 350-450 mm. In particular, the inner diameter may be sized to accommodate or otherwise engage with the susceptor 145 to form a seal between an outer edge of the susceptor 145 and the inner wall of the flow control ring.

In various embodiments, the flow control ring 210 may comprise a plurality of sections, such as a first section 300, a second section 305, a third section 310, and a fourth section 315. In an exemplary embodiment, each section represents a quarter (i.e., one-fourth, ¼) of the flow control ring 210, such that four (4) sections makes up the entire flow control ring 210.

In various embodiments, at least one section of the flow control ring 210 has a height that is different from a different section. For example, the second, third, and fourth sections 305, 310, 315 have a first height H1 and the first section 300 has a second height H2 that is greater than the first height H1. Alternatively, the second and fourth sections 305, 315 may have a first height H1 and the first and third sections 300, 315 may have a second height, or any other desired combinations. In an exemplary embodiment, the first height H1 may have a range from 8 mm to 13 mm and the second height H2 may have range from 8 mm to 13 mm.

In various embodiments, the section that has the greatest height may be radially aligned with the gate valve 125. Additionally, or alternatively, the section that has the greatest height may be radially aligned with the exhaust port 150. For example, one or more of the gate valve 125 and the exhaust port 150 may be adjacent to the outer edge 325 of the flow control ring 210. For example, in a case where the first section 300 is radially aligned with the gate valve 125, the first section 300 may have the largest height relative to the second, third, and fourth sections 305, 310, 315.

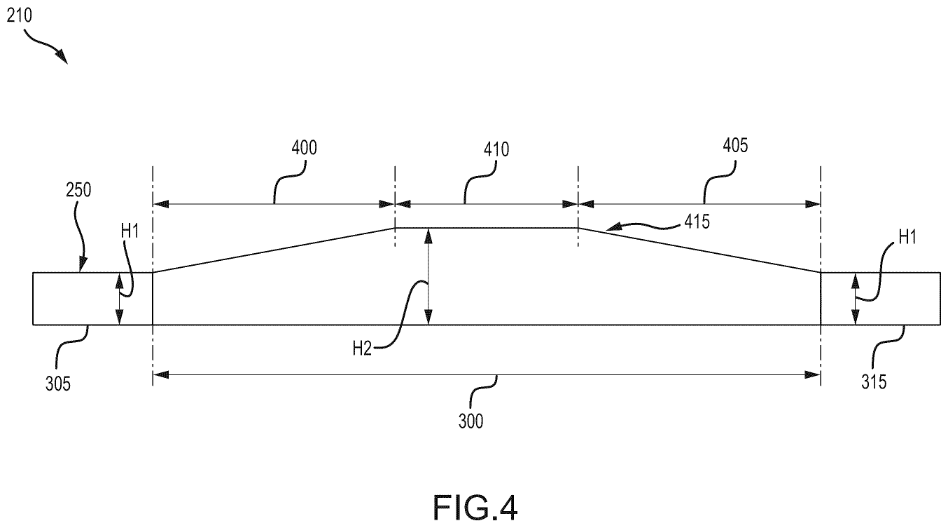

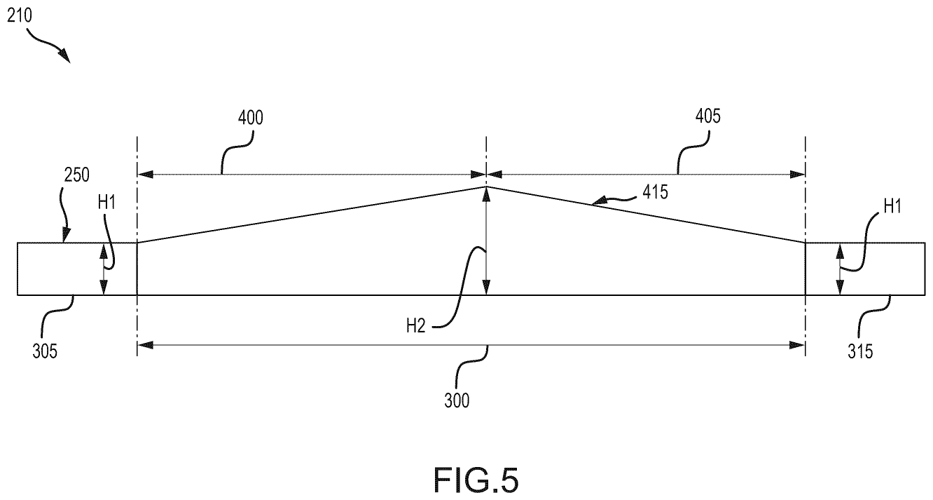

In various embodiments, and referring to FIGS. 4-5, the top surface 250 of at least a portion of the flow control ring 210 may have a tapered (i.e., sloped) profile. In an exemplary embodiment, the section having the largest height may have the tapered profile. For example, the second and fourth sections 305, 315 may have the first height and the first section 300 may have the second height. The first section 300 may also have a tapered profile. For example, the first section 300 may comprise a first region 400 having a tapered profile that slopes upwards from the second section 305. The first section 300 may further comprise a second region 405 having a tapered profile that slopes downward towards the fourth section 315. In various embodiments, the tapered profile changes linearly.

In various embodiments, the top surface 250 of the flow control ring 210 may further comprise a third region 410 having a horizontal profile disposed between two tapered profiles. For example, the third region 410 connects the first region 400 to the second region 405. In various embodiments, the horizontal profile may have a width in a range of 10 mm to 20 mm.

In operation, and referring to FIGS. 1-6, the system 100 may be configured to perform atomic layer deposition (ALD), wherein the precursor from the vessel 135 is pulsed into the reaction space 117 via the gas distribution system 110 and then purged using an inert gas, such as argon. For example, during the pulsing step, vapor flows from the vessel 135, into the inlet plenum 235, through the through-holes 240 and into the reaction space 117. During the purging step, the chemical vapor from the pulsing step is evacuated from the reaction space 117 by flowing the inert gas from the inert gas source 130 into the inlet plenum 235, through the through-holes 240, and into the reaction space 117. At this time, the exhaust system 140 is utilized and the vapor is able to flow radially outwards from the reaction space 117, through the gaps 220, 225, and into the exhaust plenum 245. The varying height of the flow control ring 210 provides a flow bias since it provides some areas of low conductance and some areas of higher conductance. This flow bias may be used to compensate for other biases caused by the exhaust port, the gate valve, or the like.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a reaction chamber comprising a sidewall;
a gas distribution system arranged above the reaction chamber and comprising:
a showerhead plate comprising an inlet plenum fluidly coupled to a plurality of inlet through-holes; and
an exhaust plate comprising an exhaust plenum;
a gate valve disposed within the sidewall of the reaction chamber;
an exhaust port disposed within the sidewall of the reaction chamber; and
a flow control ring disposed between the exhaust plate and the reaction chamber, and comprising a plurality of sections, wherein at least one section has a height that is greater than a height of a different section.

2. The apparatus according to claim 1, wherein the plurality of sections consists of a first quarter section, a second quarter section, a third quarter section, and a fourth quarter section.

3. The apparatus according to claim 2, wherein the second, third, and fourth sections have a first height and the first section has a second height that is greater than the first height.

4. The apparatus according to claim 3, wherein the first section is radially aligned with the gate valve.

5. The apparatus according to claim 3, wherein the first section is radially aligned with the gate valve and the exhaust port.

6. The apparatus according to claim 3, wherein the first height has a range from 8 mm to 13 mm and the second height has range from 8 mm to 13 mm.

7. The apparatus according to claim 1, wherein the flow control ring comprises a top surface comprising a first region having an upward tapered profile in a first direction and a second region having a downward tapered profile in an opposite, second direction.

8. The apparatus according to claim 7, wherein the top surface further comprises a third region having a horizontal profile disposed between the first and second regions, the horizontal profile having a width of 10 mm to 20 mm.

9. The apparatus according to claim 1, wherein the flow control ring and exhaust plate are separated by a gap in the range of 0.1 mm to 2 mm.

10. The apparatus according to claim 1, wherein the flow control ring comprises a top surface having a tapered profile.

11. An apparatus, comprising:
a reaction chamber;
a gas distribution system arranged above the reaction chamber and comprising:
a showerhead plate comprising an inlet plenum fluidly coupled to a plurality of inlet through-holes; and
an exhaust plate comprising an exhaust plenum; and
a flow control ring disposed between the exhaust plate and the reaction chamber, and comprising a plurality of sections, wherein the plurality of sections consists of a first quarter section, a second quarter section, a third quarter section, and a fourth quarter section, and wherein the second, third, and fourth sections have a first height and the first section has a second height that is greater than the first height.

12. The apparatus according to claim 11, wherein the flow control ring and exhaust plate are separated by a gap in the range of 0.1 mm to 2 mm.

13. The apparatus according to claim 11, wherein the flow control ring comprises a top surface having a tapered profile.

14. The apparatus according to claim 11, wherein the flow control ring comprises a top surface comprising a first region having a tapered profile in a first direction and a second region having a tapered profile in an opposite, second direction.

15. The apparatus according to claim 14, wherein the top surface further comprises a third region having a horizontal profile disposed between the first and second regions, the horizontal profile having a width of 10 mm to 20 mm.

16. The apparatus according to claim 14, wherein the tapered profiles are linear.

17. The apparatus according to claim 11, wherein the first height has a range from 8 mm to 13 mm and the second height has range from 8 mm to 13 mm.

18. An apparatus, comprising:
a reaction chamber comprising a sidewall;
an exhaust plate disposed above the reaction chamber and comprising an exhaust plenum and an exhaust disk disposed within the exhaust plenum, wherein the exhaust disk comprises a plurality of through-holes in fluid communication with the exhaust plenum;
a gate valve disposed within the sidewall of the reaction chamber;
an exhaust port disposed within the sidewall of the reaction chamber; and
a flow control ring disposed between the exhaust plate and the reaction chamber, and comprising a plurality of sections, wherein at least one section comprises a top surface having a linearly-tapered profile and a height that is greater than a height of a different section.

19. The apparatus according to claim 18, wherein the top surface further comprises a region having a horizontal profile disposed between the first and second regions, the horizontal profile having a width of 10 mm to 20 mm.

20. The apparatus according to claim 18, wherein the at least one section is radially aligned with at least one of the gate valve and the exhaust port.
